(19) United States
(12) Patent Application Publication
(10) Pub. No.: US 2008/0224121 A1
(43) Pub. Date: Sep. 18, 2008

(54) SPONTANEOUS EMISSION OF TELECOMMUNICATION WAVELENGTH EMITTERS COUPLED TO AT LEAST ONE RESONANT CAVITY

(76) Inventors: Ranojoy BOSE, Flushing, NY (US); Chee Wei WONG, New York, NY (US); Jie GAO, New York, NY (US)

Correspondence Address: WilmerHale/Columbia University, 399 PARK AVENUE, NEW YORK, NY, 10022, US

(21) Appl. No.: 12/029,934

(22) Filed: Feb. 12, 2008

Related U.S. Application Data
(63) Continuation-in-part of application No. PCT/US06/31637, filed on Aug. 14, 2006.
(60) Provisional application No. 60/707,598, filed on Aug. 12, 2005.

(51) Int. Cl. H01L 33/00

(52) U.S. Cl. 257/13; 438/31; 257/E33.003

(57) ABSTRACT

Systems and methods for devices that include a structure having at least one resonant cavity and at least one emitter having an emission frequency that is substantially in the telecommunication wavelengths are provided. The emission frequency can be coupled to the resonant frequency of resonant cavity so that emitted wavelengths corresponding to the resonant wavelengths of the resonant cavity are enhanced. Moreover, the devices of the present invention may be capable of operating at room temperatures.

### CROSS-REFERENCE(S) TO RELATED APPLICATIONS

The present application claims the benefit of U.S. Patent Application No. 60/707,598, filed on Aug. 12, 2005, and PCT Application No. PCT/US06/031637, filed on Aug. 14, 2006, the contents of which are hereby incorporated by reference herein in their entireties.

### FIELD OF THE INVENTION

The present invention relates to spontaneous emission of photons in certain structures. More particularly, the present invention relates to emitters spontaneously emitting photons that are coupled with resonant cavity structures.

### BACKGROUND OF THE INVENTION

Control of photons has been an active area of research recently due to their numerous potential applications ranging from quantum computing, lasers, and telecommunications. However, numerous different hurdles must be overcome before such devices can be utilized in practical applications. For example, the ability operate in industry-standard wavelength ranges, the ability to fabricate such devices using easily adaptable processing methods, the ability to provide devices that operate at room temperature, and the like are critical. To date, however, none of the devices provide suitable solutions to overcome such hurdles.

### SUMMARY OF THE INVENTION

The present invention relates to devices that include a structure having at least one resonant cavity and at least one emitter having an emission frequency that is substantially in the telecommunication wavelengths, where the emission frequency can be coupled to the resonant frequency of a resonant cavity so that emitted wavelengths corresponding to the resonant wavelengths of the resonant cavity are enhanced. Moreover, the devices of the present invention may be capable of operating at room temperatures.

The present invention also relates to methods for forming the devices of the present invention. Methods of the present invention may include forming a suitable resonant cavity structure, providing one or more emitters having an emission frequency that is substantially in the telecommunication wavelengths to be coupled with the resonant frequency of the resonant cavity structure.

The present invention further relates to numerous different systems and methods for utilizing the devices of the present invention, such as single photon sources, indistinguishable photon sources, lasers, quantum computers, quantum key decoders, and the like.

### BRIEF DESCRIPTION OF THE DRAWINGS

The above and other objects and advantages of the present invention will be apparent upon consideration of the following detailed description, taken in conjunction with the accompanying drawings, in which like reference characters refer to like parts throughout, and in which:

FIG. 1 is a diagram of various different types of photonic crystals in accordance with certain embodiments of the present invention;

FIG. 2 shows a band diagram of a 2D triangular lattice of air cylinders in silicon in accordance with certain embodiments of the present invention;

FIG. 2A shows a band diagram of a 2D triangular lattice of polymethyl methacrylate cylinders in silicon in accordance with certain embodiments of the present invention;

FIG. 3 shows a resonant cavity in a 2D photonic crystal where three of the air cylinders arranged in a linear fashion are replaced with a small central air cylinder in accordance with certain embodiments of the present invention;

FIG. 3A shows a plot of Q versus the radius of the center defect hole for the resonant cavity structure of FIG. 3 taking the refractive index of the center defect hole to be 2.0 in accordance with certain embodiments of the present invention;

FIG. 3B shows the spontaneous emission enhancement factor versus spatial overlap for a the resonant cavity structure of FIG. 3 in accordance with certain embodiments of the present invention;

FIG. 4 shows a resonant cavity in a 2D photonic crystal where one air cylinder is replaced with a smaller air cylinder in accordance with certain embodiments of the present invention;

FIG. 4A shows the Lorentzian dependence of the emitter and resonant cavity mismatch (or detuning) for various emitter wavelengths for the resonant cavity structure of FIG. 4 in accordance with certain embodiments of the present invention;

FIG. 4B shows the spontaneous emission enhancement factor versus spatial overlap for a the resonant cavity structure of FIG. 4 in accordance with certain embodiments of the present invention;

FIG. 5 shows a resonant cavity in a 2D photonic crystal where three air cylinders are replaced with a linear air defect in accordance with certain embodiments of the present invention;

FIG. 6 shows a resonant cavity in a 2D photonic crystal where 19 air cylinders are replaced with 12 smaller air cylinders arranged in a circular pattern in accordance with certain embodiments of the present invention;

FIG. 7 shows a supersymmetric hexagonal array of twelve different resonant cavities in a 2D photonic crystal in accordance with certain embodiments of the present invention;

FIG. 8 shows heterostructure mode-gap cavities where four of the air cylinders nearest to the resonant cavity have been displaced slightly from the triangular lattice of air cylinders in accordance with certain embodiments of the present invention;

FIG. 9 shows microdisks having high-Q resonances and directional emission in accordance with certain embodiments of the present invention;

FIG. 10 shows an exemplary schematic of an optical setup to pump a nanocrystal-resonant cavity system in accordance with certain embodiments of the present invention;

FIG. 11 shows an exemplary cross-section of a setup to electrically pump a nanocrystal-resonant cavity system in accordance with certain embodiments of the present invention;

FIG. 12 shows an energy dispersive x-ray (EDX) spectrum of a PbS quantum dot infiltrated into the air cylinders of a 2D silicon photonic crystal in accordance with certain embodiments of the present invention;

FIG. 13 shows an exemplary schematic of a setup to utilize the device of the present invention in a single photon source system in accordance with certain embodiments of the present invention;

FIG. 14 shows an exemplary schematic of a setup to utilize the device of the present invention in an indistinguishable photon source system in accordance with certain embodiments of the present invention;

FIG. 15 shows an exemplary schematic of a setup to utilize the device of the present invention in quantum key distribution system in accordance with certain embodiments of the present invention;

FIG. 16 shows a resonant cavity in a 2D photonic crystal where three of the air cylinders are replaced with a small central air cylinder in accordance with certain embodiments of the present invention;

FIG. 16A shows a scanning electron microscope image of a resonant cavity in a 2D photonic crystal where three of the air cylinders are replaced with a small central air cylinder in accordance with certain embodiments of the present invention;

FIG. 17 shows graphs of cold-cavity modes of the device shown in FIG. 16A with a 100 nm of PMMA coating obtained using a tunable laser in accordance with certain embodiments of the present invention;

FIG. 18 shows a schematic of the imaging/characterization system in accordance with certain embodiments of the present invention;

FIG. 19A shows a graph of quantum dot-cavity coupling measurements in accordance with certain embodiments of the present invention;

FIG. 19B shows a graph of normalized cavity measurement in accordance with certain embodiments of the present invention; and

FIG. 19C shows a graph of polarized coupling measurement in accordance with certain embodiments of the present invention.

### DETAILED DESCRIPTION OF THE INVENTION

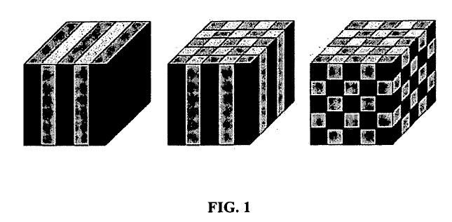

Photonic crystals prohibit propagation of electromagnetic radiation within certain frequency bandgaps. A photonic crystal, similar to an atomic crystal (such as silicon) that has a periodic arrangement of atoms or molecules, has a periodic arrangement of dielectric materials. Hence, just as a periodic electronic potential in an atomic crystal introduces energy bandgaps so that electrons are forbidden to propagate in certain directions within certain energy ranges, certain dielectric contrast in photonic crystals can lead to the formation of photonic bandgaps that prohibit the propagation of photons. As schematically illustrated in FIG. 1, such dielectric periodicities (different colors representing different materials having different dielectric constants) can exist in one-dimension (1D), two-dimensions (2D), or three-dimensions (3D), and these photonic crystals are termed 1D photonic crystals, 2D photonic crystals, and 3D photonic crystals, respectively.

Various software packages, such as MPB (see S. G. Johnson and J. D. Joannopoulos, Optics Express, vol. 8, p. 173 (2001), the content of which is hereby incorporated by reference herein in its entirety), MEEP (see D. Roundy, M. Tbanescu, P. Bermel, A. Farjadpour, J. D. Joannopoulos, and S. G. Johnson, The Meep FDTD package, http://ab-initio.mit.edu/meep/), FullWAVE from RSoft Design Group (see http://www.rsoftdesign.com/products/component_design/FullWAVE/), and BandSOLVE from RSoft Design Group (see http://www.rsoftdesign.com/products/component_design/BandSOLVE/), can be utilized to calculate the energy band diagrams (also called band structures) of various 1D, 2D, and 3D photonic crystals.

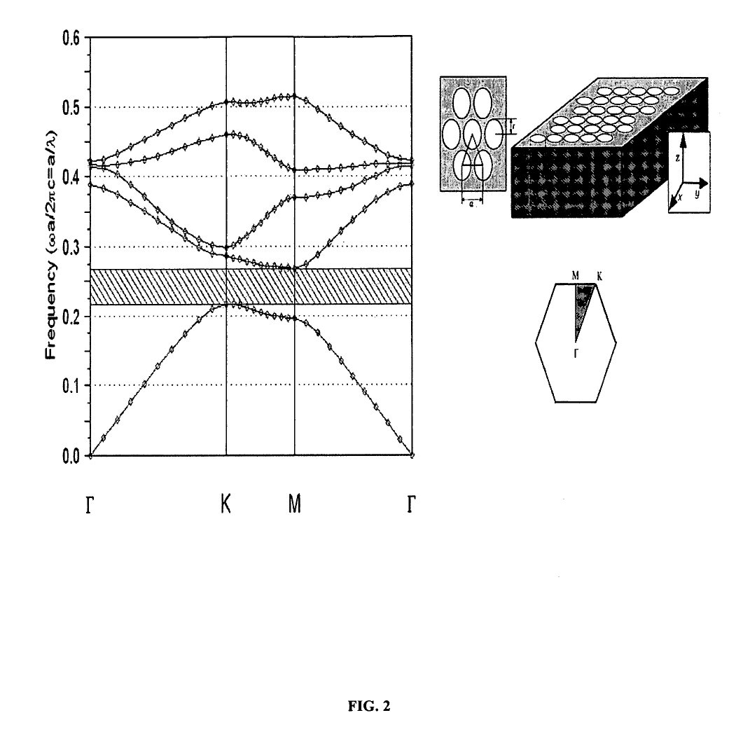

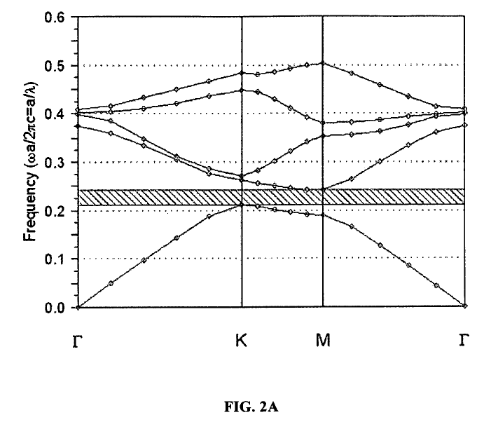

FIG. 2 shows the transverse electric field band diagram of a 2D photonic crystal having a triangular lattice of air cylinders embedded in a dielectric material having a refractive index (n) of about 3.46 (i.e., dielectric constant (∈=n²) is about 11.97). TE modes represent transverse-electric modes where the electric field of the electromagnetic radiation is confined to the xy-plane of the 2D photonic crystal and TM modes (not shown) represent transverse-magnetic modes where the magnetic field of the electromagnetic radiation is confined to the xy-plane of the 2D photonic crystal. As shown, a TE bandgap can exist between normalized frequencies, f of about 0.22 to about 0.27 (i.e., the region which prohibits the propagation of TE modes in the xy-plane of the 2D photonic crystal). When the effective index of the slab is utilized to take into account the 2D nature of the photonic crystal, a TE bandgap can exist between normalized frequencies, f, of about 0.256 and about 0.321 (not shown). Once the normalized frequencies for the photonic bandgaps is calculated, appropriate wavelengths of light (λ) or the unit cell lattice spacing (a) can be designed and/or selected using the relationship f=a/λ.

It should be noted that the frequency range of the photonic bandgaps can be tuned by changing (a) the unit cell lattice spacing, (b) radius of the air cylinders, and/or (c) the dielectric contrast between the air cylinders and the matrix of the 2D photonic crystal. For example, because photonic bandgaps arise through periodic dielectric contrast in the photonic crystal, decreasing the dielectric contrast while maintaining the remaining two variables ((a) and (b)) constant can lead to a narrower range of the photonic bandgaps. Moreover, decreasing the unit cell lattice spacing while maintaining the remaining two variables ((b) and (c)) constant can shift the photonic bandgap to higher normalized frequencies. Decreasing the radius of the air cylinders while maintaining the remaining two variables ((a) and (c)) constant can shift the photonic bandgap to lower normalized frequencies. FIG. 2A shows another exemplary band structure calculation wherein the air cylinders have been replaced with a polymethyl methacrylate (PMMA) material, which can effectively lower the dielectric contrast. As shown, the bandgap can be narrowed.

If one or more defects are introduced into the periodic structure, certain frequencies that lie within the photonic bandgap can be permitted in the vicinity of the defects. For example, introduction of a point defect (also called a resonant cavity or a nanocavity) into a 2D photonic crystal structure can allow the existence of a localized evanescent mode, which can decay exponentially away from the defect site. The “quality factor,” Q, which is a measure of how many oscillations take place in a cavity before damping eventually dissipates away the original excitation, is a measure of the exponential decay rate (κ=ω/2Q, where ω is the resonant frequency of the cavity). Making the Q value to be very high to minimize the damping and confine light inside the resonant cavity can involve certain design optimization of the resonant cavity and the photonic crystal. Moreover, even if the Q values are high and the defect-induced states are localized in the xy-plane, they can escape in the z-direction if suitable measures (e.g., providing a capping layer to allow total internal reflection) are not taken. Nevertheless, by introducing one or more defects within a photonic crystal, a single or few highly localized electromagnetic modes that lie within the photonic bandgap may be supported since the cavity can act as a Fabry-Perot resonator by allowing for a build-up of the vacuum field modes within a very small volume (V). The volume that contains the electromagnetic modes near the resonant cavity structure is called a mode volume (Vₘ). Generally, it may be possible to optimize a design of the resonant cavity structure to obtain desired Vₘ and/or Q values. In other words, it may possible to confine electromagnetic fields with very narrow linewidths within the forbidden region of the photonic crystal by introducing point defects in an otherwise periodic background.

As will be readily apparent to one of ordinary skill in the art, there are many different ways to introduce defects in a photonic crystal structure. For example, in the 2D photonic crystal shown in FIG. 2, the radius of one of the air cylinders may be reduced or enlarged. The radius of the defect can be reduced to zero (corresponding to a missing air cylinder in the 2D) or increased to envelop an entire unit cell of the 2D photonic crystal. Calculation of the defect modes shows that the permitted frequencies can be tuned to any value within the photonic bandgap by altering the size of the defect.

Furthermore, when one or more material capable of spontaneous emission (also called emitters or excitons) are introduced into the defect site of the photonic crystal, the spontaneous emission characteristics can be modified (see, e.g., Purcell, E. M., Phys. Rev. vol. 69, (1946) p. 681, the content of which is hereby incorporated by reference herein in its entirety).

Spontaneous emission is a process in which an excited energy state of a material drops to a lower energy state, resulting in the emission of photons. In spontaneous emission, if the material is in an excited state with energy E₂ and decays spontaneously into an energy state having energy E₁, a photon having a certain frequency can be released (the energy of the emitted photon usually not exceeding the difference between the two energy states, E₂-E₁).

Moreover, if N number of excited states exists, the rate at which spontaneous emission occurs is given by

$$\frac{\partial N}{\partial t} = - {A}_{21} N \qquad [ 1 ]$$

where A₂₁ is a material/transition constant for a particular material and transition that occurs. As shown in Equation [1], the rate of emission is proportional to the number (density) of excited states.

To calculate the number of excited states at a given time, N(t), Equation [1] above can be solved to give

$$N ( t ) = N ( 0 ) exp ( - \frac{t}{{τ}_{21}} ) \qquad [ 2 ]$$

where N(0) is the number of excited states at time zero and τ₂₁ is the lifetime of transition (also called relaxation lifetimes) and is equal to 1/A₂₁. As shown above, the number of excited states decays exponentially and is related to the material/transition constant, A₂₁.

Generally, the phase of the emitted photons as well as the direction of the emitted photons are random because the radiation field contains an infinite set of harmonic oscillators and the spontaneous emission lifetimes of nanocrystal excitons are comparable with the dephasing times (also called dephasing lifetimes). Hence, successive photons emitted from the nanocrystals in free space are generally not correlated and their wavepackets are also generally not identical.

Although spontaneous emission has long been regarded as an immutable property of matter, correlated and indistinguishable photons can be produced when emitters are introduced into defect sites of a photonic crystal, due to the coupling of the excitons to a cavity resonance. The interaction of the emitted wavelengths with the resonant cavities are the subject of cavity quantum electrodynamics (cQED) of the quantum nature of coherent interactions of matter (such as atoms or atom-like nanocrystals) with the electromagnetic fields inside open cavity systems. Radiative decay (or decoherence) from the open cavity systems can be designed to be small, compared to cavity-mediated atom-field interactions. CQED of a two-level emitter (or dressed excitons polaritons in low excitation levels) in a single-mode optical cavity can be governed by the dynamical master equation

$$\hat{ρ} = \frac{1}{i ℏ} [ \hat{H} , ρ ] + κ ( \begin{matrix}2 \hat{a} ρ \hat{a} - {\hat{a}}^{+} \hat{a} ρ - \\ ρ \hat{a} {\hat{a}}^{+}\end{matrix} ) + ( \frac{γ}{2} ) ( \begin{matrix}2 {\hat{σ}}_{-} ρ {\hat{σ}}_{+} - {\hat{σ}}_{+} {\hat{σ}}_{-} ρ - \\ ρ {\hat{σ}}_{+} {\hat{σ}}_{-}\end{matrix} ) \qquad [ 3 ]$$

where ρ is the density operator, γ is the spontaneous emission rate of the emitter into modes other than the cavity mode, κ(=ω/2Q) is the cavity field decay rate, â⁺ and â are the boson creation and annihilation operators for the cavity mode, and \hat{σ}₊ and \hat{σ}₋ are the raising and lowering operators for the emitter. The field can be eliminated in the above evolution equation under the Born-Markov approximation. Ĥ is a non-Hermitian Hamiltonian expressed as

$$\hat{H} = \frac{{\hat{p}}^{2}}{2 m} + ℏ ( ω - {ω}_{o} ) {\hat{a}}^{+} \hat{a} + ℏ ( ω - {ω}_{o} ) {\hat{σ}}_{+} {\hat{σ}}_{-} + i ℏ g ( {\hat{σ}}_{-} {\hat{a}}^{+} - {\hat{σ}}_{+} \hat{a} ) \qquad [ 4 ]$$

where the first term of the Hamiltonian represents the kinetic energy operator, the second and third terms represent the detuning of the cavity mode and the emitter from the driving source, and the fourth term represents the Jaynes-Cummings Hamiltonian. The Jaynes-Cummings Hamiltonian can represent the emitter-cavity interaction under the electric dipole approximation. In this term, g is the coherent atom-field dipole coupling rate, given as

$${[ ( \frac{1}{4 π ɛ} ) ( \frac{π {e}^{2} f}{m {V}_{m}} ) ]}^{1 / 2} ,$$

with the emitter located at the antinode of cavity's standing wave. Here, e is the electron change, m is the free electron mass, f is the exciton oscillator strength, and Vₘ is the cavity mode volume.

When an emitter is placed inside a resonant cavity, certain frequencies in the emission spectrum of the emitter can be enhanced while the other frequencies in the emission spectrum can be inhibited generally leading to a significantly narrowed emission spectrum. Such modification of spontaneous emission characteristics for emitters in a resonant cavity can be divided into two different regimes: weak coupling and strong coupling.

### Weak Coupling Regime

In the weak coupling regime (g<(κ,γ)), the spontaneous emission characteristics can be modified according to the Purcell effect where on-resonance modes are enhanced while off-resonance modes are inhibited. Generally, excitonic transitions (i.e., the emitted frequencies) that occur at the field resonances of the resonant cavity can see a sufficiently large photon-field density of states, resulting in enhanced spontaneous emissions (shorter lifetimes) as compared to those occurring in free space. However, excitonic transitions occurring outside the cavity field resonance frequencies see inhibited spontaneous emission (longer lifetimes) compared to those occurring in free space (see G. S. Solomon, M. Pelton, Y. Yamamoto, Phys. Rev. Lett. Vol. 86, (2001), p. 3903, the content of which is hereby incorporated by reference herein in its entirety).

On resonance, the spontaneous emission can be enhanced by the Purcell factor

$${F}_{p} = \frac{3 {λ}_{c}^{3}}{4 {π}^{2} {n}^{3}} \frac{Q}{{V}_{m}} ,$$

where λ_{c} is the wavelength of the cavity resonance, n is the refractive index of the medium, Q is the quality factor, and Vₘ is the mode volume. If the emission spectrum of the quantum dots is significantly larger than the cavity linewidth, the spontaneous emission may be mainly dependent on (1/Vₘ) with little contribution from Q. Hence, during design optimization, it may be beneficial to design a resonant cavity structure by first focusing on obtaining a small Vₘ value and then trying to further enhance Q factors thereafter. Moreover, the resonance-exciton dynamics may be irreversible and emitted photons can eventually leak out of the cavity.

The present invention may also be utilized in a different weak coupling regime where κ˜g>γ. Here, both critical photon and emitter numbers can still be much less than 1 while allowing the photon (or even entangled photon pairs) to be emitted from the cavity as quickly as possible (without oscillations in the strong coupling regime). Hence, low quality factors (e.g., 770) may be needed (κ=790 GHz), which is based on the emitter-field dipole decay rate for various different resonant cavity designs.

### Strong Coupling Regime

In the strong coupling regime (g>(κ,γ)), the coupling strength of the emitter-cavity interaction, g₀, can be larger than the decay rates of both the nanocrystal and the resonant cavity (see T. Yoshi, A. Scherer, J. Hendrickson, G. Khitrova, H. M. Gibbs, G. Rupper, C. Ell, O. B. Shchekin, and D. G. Deppe, Nature, vol. 432 (2004), p. 200, the content of which is hereby incorporated by reference herein in its entirety). In other words, if the emitters are excited to cause spontaneous emission, the emitted light can act as a coherent source of photons due to the strong confinement within the resonant cavity to cause the cyclic absorption and emission of the photons by a stimulated emission. (Stimulated emission is a process by which a material is excited by a photon resulting in the generation of another photon). One such cycle of absorption and emission is called a Rabi cycle and the inverse of the Rabi cycle duration is called the Rabi frequency, which is another measure of the coupling strength (i.e., g). Hence, unlike the weak coupling interaction described above, the field-exciton dynamics is reversible. Moreover, if the coupling between the cavity field and the exciton is strong enough so that the number of photons exiting the system at any time can be effectively controlled, the nanocrystal-cavity system can operate as a single photon source.

It should be noted that the number of photons required to dramatically change the emitter response (termed “critical photon number”=γ²/4g²) is <<1 and the number of emitters needed to dramatically affect the cavity field (termed “critical emitter number”=2γκ/g²) is <<1 in the strong coupling regime. These parameters can also be viewed as the relative strengths of the incoherent versus coherent processes.

In addition, the cavity resonance can also exhibit a splitting by the Rabi frequency, and two peaks can be observed in emission. That is, in the strong coupling regime, rather than observing a single emission peak, two peaks can be observed where one peak is attributed to the emitter and the other peak is attributed to the resonant cavity's resonance peak (see T. Yoshi, A. Scherer, J. Hendrickson, G. Khitrova, H. M. Gibbs, G. Rupper, C. Ell, O. B. Shchekin, and D. G. Deppe, Nature, vol. 432 (2004), p. 200; and J. P. Reithmaler, G. Sek, A. Loffler, C. Hofmann, S. Kuhn, S. Reitzenstein, L. V. Keldysh, V. D. Kulakovskil, T. L. Reinecke, and A. Forchel, Nature, vol. 432, (2004) p. 197, the content of which are hereby incorporated by reference herein in their entirety). Without sufficiently strong coupling, the location of the peaks can change with temperature and the location of the peaks can “cross” with changing temperatures. However, strong coupling can result in an anti-crossing behavior between the nanocrystal and cavity resonances where the crossing of the respective peaks do not occur (see T. Yoshi, A. Scherer, J. Hendrickson, G. Khitrova, H. M. Gibbs, G. Rupper, C. Ell, O. B. Shchekin, and D. G. Deppe, Nature, vol. 432 (2004), p. 200, the content of which is hereby incorporated by reference herein in its entirety).

### Exemplary Resonant Cavity Designs

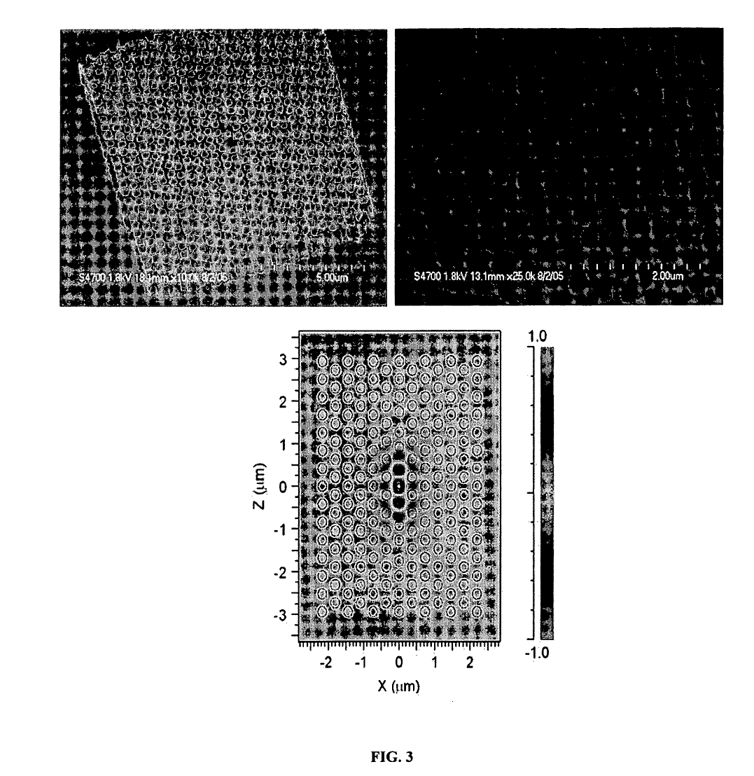

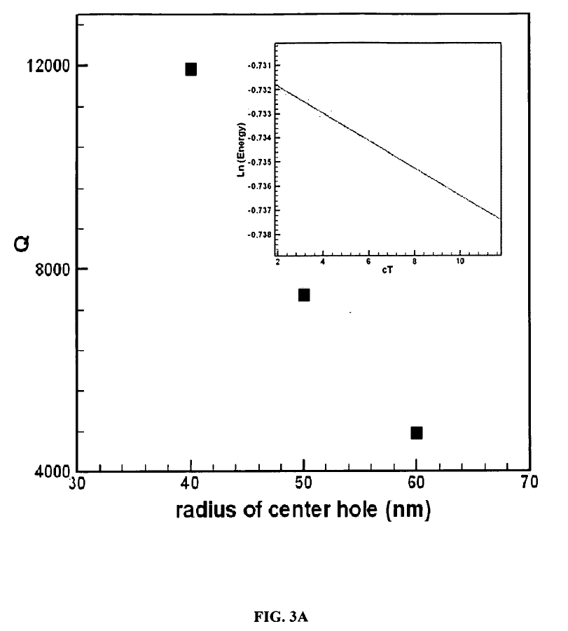

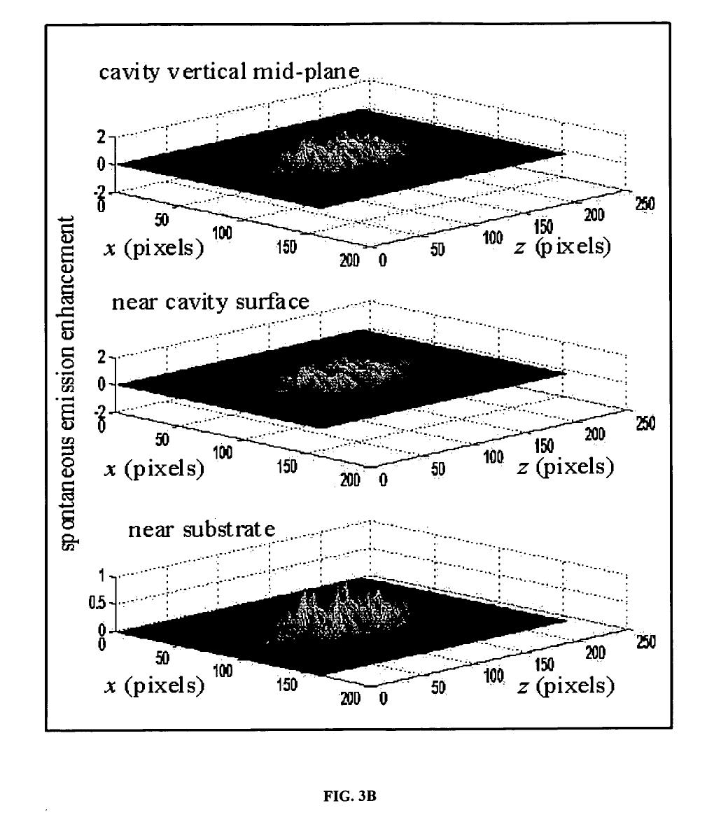

FIGS. 3 through 8 show several exemplary structures having at least one resonant cavity. In certain embodiments, the emitted frequency from the resonant cavity may be near 1.55 μm, allowing for integrated silicon photonics and on-chip device operation at telecommunication wavelengths. As used herein, telecommunication wavelengths correspond to wavelengths that range from about 1.40 μm to about 1.65 μm, such as from about 1.45 μm to about 1.60 μm, or from about 1.52 μm to about 1.58 μm.

As shown, in certain embodiments, the resonant cavity can be fabricated in a 2D photonic crystals based on a triangular lattice of low dielectric cylinders surrounded by a high dielectric material. In certain embodiments described below, the low dielectric cylinders can be air cylinders and the high dielectric material can be silicon. The 2D photonic crystal can lie on top of a SiO₂ substrate. In certain embodiments, a=420 nm, r=0.29 a (±10%), and t=0.6 a, where a is the period, r is the radius of the air cylinders, and t is the thickness of the slab. With the design parameters as identified above, the photonic bandgap may exist from about 1300 nm to about 1650 nm and the permitted wavelengths in the resonant cavity may be about 1550 nm.

In certain embodiments, the 2D photonic crystal can incorporate waveguides that allow for numerous applications, such as lensed optical fiber waveguide coupling and characterization of the nanocavities using radiation collection measurements.

### First Design

FIG. 3 shows a first design where the 2D photonic crystal is modified by replacing three of the air cylinders arranged in a linear fashion with a small central air cylinder (r_{c}) to obtain a resonant cavity (L3 structure). In certain embodiments, emitters can be placed in the small central hole. In certain embodiments, the radii of the smaller air cylinder can be about 100 nm, although other suitable radii will be readily apparent to one of ordinary skill in the art. As shown, the electric field anti-node can be localized within the center defect hole, allowing for the field to couple with the quantum dot nanocrystal(s) infiltrated into the center defect hole.

Taking the refractive index of the center defect hole to be about 1.7, Q=5600 can be obtained. Q can be calculated from Equation [5] below

$$Q = \frac{2 π s}{λ} \qquad [ 5 ]$$

by plotting the energy decay (in logarithmic scale) in the resonant cavity as a function of distance measuring the slope (s) of the curve (see inset of FIG. 3A). FIG. 3A shows a plot of Q versus the radius of the center defect hole taking the refractive index of the center defect hole to be 2.0.

FIG. 3B shows the spontaneous emission enhancement factor versus spatial overlap for a specific cavity illustrated in FIG. 3. The enhancement in spontaneous emission for an emitter positioned at the maximum of the electric field intensity of the cavity field mode, and polarization-matched to the cavity field mode, is given by the equation [6]:

$$E = {F}_{p} \times \frac{{γ}_{c} ( 2 {γ}_{e} + {γ}_{c} )}{4 {( 1 - \frac{{ω}_{c}}{{ω}_{e}} )}^{2} + {( 2 {γ}_{e} + {γ}_{c} )}^{2}} \times \frac{{\vert {E}_{r} \vert}^{2}}{{\vert {E}_{max} \vert}^{2}} + {F}_{PhC} \qquad [ 6 ]$$

where Fₚ is the Purcell Factor, ω_{c} and ωₑ are the frequencies of the cavity resonance and emitter respectively, and γₑ and γ_{c} are the emitter and cavity linewidths respectively. F_{PhC} is an inhibition factor that can be induced by the photonic crystal lattice. When the emitter's homogeneous linewidth, γₑ is large (as may be the case with PbS nanocrystals), the effect of the cavity quality factor (Q) on the enhancement factor may be reduced, and the effective mode volume (Vₘ) may become more important.

In this example, a cavity resonance at 1550 nm, a cavity linewidth of 1 nm (Q˜1,550), nanocrystal photoluminescence peak at 1540 nm, and nanocrystal homogenous linewidth of 10 nm was utilized. This cavity has a mode volume of about 0.16 um³ (or ˜1.81(λ/n)³). As can be seen in FIG. 3B, the highest spontaneous emission enhancement is about 2 at optimal spatial alignment with the cavity field maximum (see FIG. 3B corresponding to cavity vertical mid-plane).

Any possible spectral mismatch that can exist in this system may be tuned by temperature tuning (e.g., when one or a few nanocrystals have been isolated in the resonant cavity environment). In addition, thermalization of homogenous linewidth can be reduced by operating at low temperatures. Moreover, the cQED enhancement and inhibition can be dependent on frequency matching, spatial matching, and polarization matching between the emitter and the resonant cavity (see H. Y. Ryu and M. Notomi, Enhancement of spontaneous emission from the resonant modes of a photonic crystal slab single-defect cavity, Opt. Lett. 28, 2390 (2003), the content of which is hereby incorporated by reference herein in its entirety).

Hence, the first design allows both strong and weak coupling regimes to be obtained by suitable adjustment of operating conditions and/or design parameters.

### Second Design

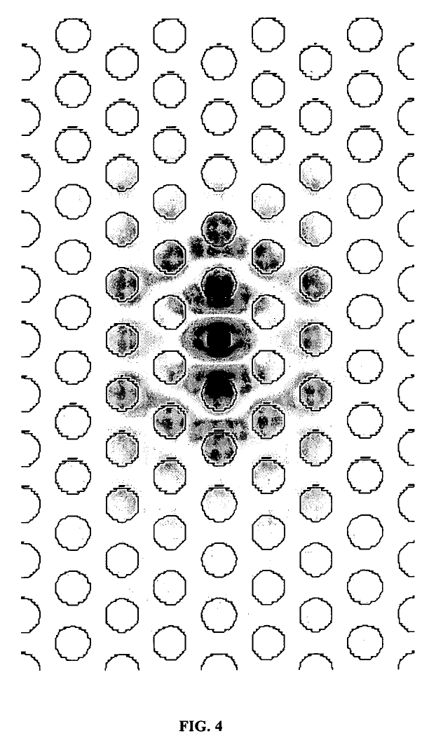

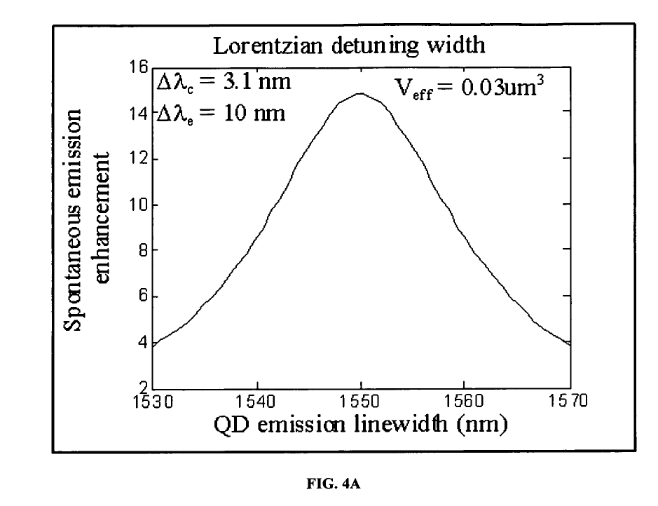

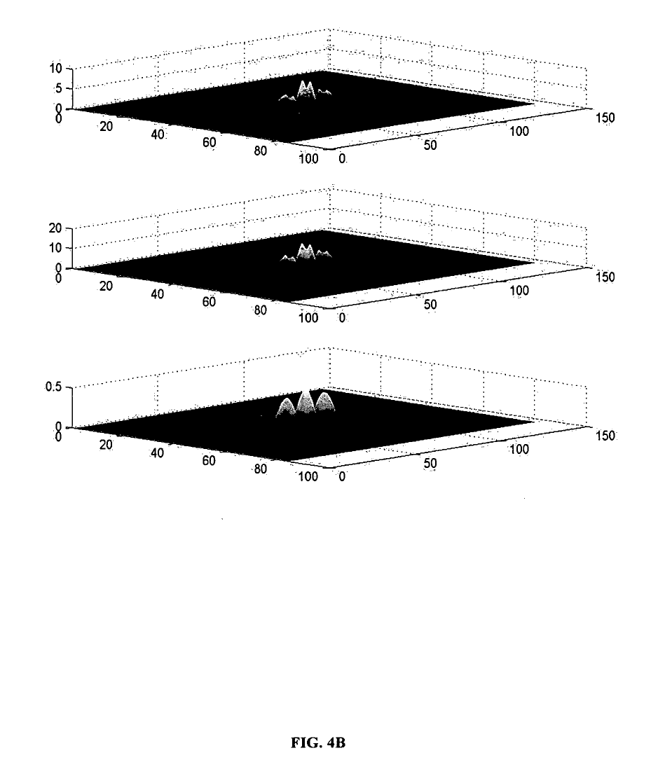

As described above, it may be beneficial in certain embodiments to design a resonant cavity structure having a small mode volume. FIG. 4 shows such a structure having one air cylinder replaced with a smaller air cylinder and the fields in the vicinity of the resonant cavity. Such a design may allow reduction in mode volume from that shown in design of FIG. 3.

FIG. 4A shows the Lorentzian dependence of the emitter and resonant cavity mismatch (or detuning) for various emitter wavelengths using a cavity resonance at 1550 nm, a cavity linewidth of 3.1 nm (Q˜500), nanocrystal photoluminescence peak between 1530 and 1570 nm, and nanocrystal homogenous linewidth of 10 nm. A modal volume (Vₘ) of 0.03 um³ (or ˜0.34(λ/n)³) can be obtained in this second design, which is smaller than the modal volume of the L3 structure described above. Moreover, unity spatial and polarization matching may be obtained. The Purcell factor is 112, with a significantly higher spontaneous emission enhancement factor of 14.8.

As shown in FIG. 4B, designing a smaller effective volume can allow for considerable increase in the enhancement factors by at least a factor of 2×. In the case of spatial matching in the cavity mid-plane, enhancement factors of about 10 can be reached.

### Third Design

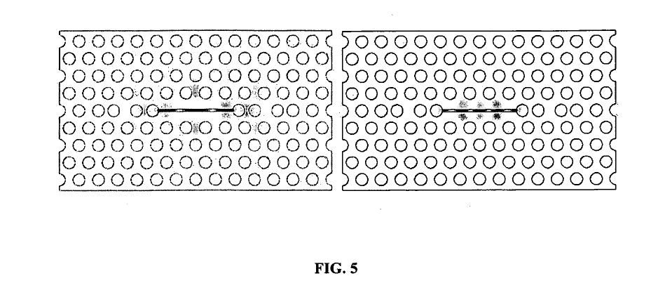

FIG. 5 shows a third design where a 2D photonic crystal having triangular lattice of air cylinders is modified by removing about 3 air cylinders and replacing them with a linear air defect. In certain embodiments, the width of the line defect may be about 40 nm and may extend at the location where the 3 air cylinders that have been removed. In certain embodiments, emitters can be placed in the line defect.

As shown in FIG. 5, the 3D FDTD simulation shows there may be two cavity modes inside the photonic bandgap, and both show extremely small mode volume. The mode volume can be 0.15(λ/2n)³ (left image) and 0.04(λ/2n)³ (right image). The quality factor (Q) of this cavity can be about 1000, while the mode volume can decrease 50˜100 times compared to original L3 design shown in FIG. 3. In the case of quantum dot-cavity mode interaction where the quality factor of the emitter dominates the enhancement, the design shown in FIG. 5 improves spontaneous emission enhancement characteristics, due to the high Purcell factor (10⁴) that is achievable.

### Fourth Design

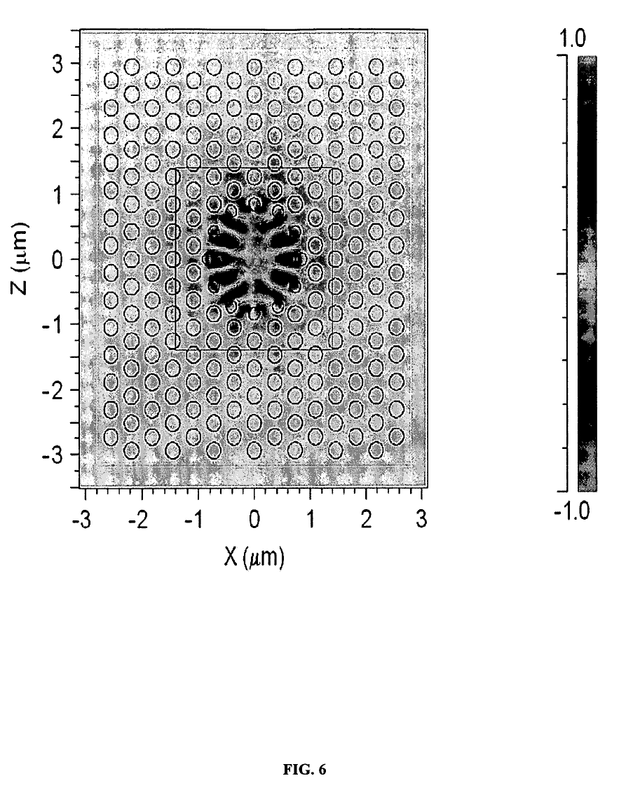

FIG. 6 shows a third design where a 2D photonic crystal having triangular lattice of air cylinders is modified by removing about 19 air cylinders and replacing them with 12 smaller air cylinders arranged in a circular pattern. In certain embodiments, emitters can be placed in the 12 smaller air cylinders arranged in a circular pattern. In certain embodiments, the radii of the smaller air cylinders can be about 100 nm.

As shown in FIG. 6, Q greater than 100,000 appears to be possible, but field maxima lie in the semiconductor region, which does not readily accommodate the infiltration of emitters. Nevertheless, the electric field does extend into the air cylinder, which may allow for some of the weaker electric fields to interact with quantum dot nanocrystals infiltrated into the defect air cylinders arranged in a circular pattern. The electric field distribution shown in FIG. 6 is referred to as a whispering gallery mode (WGM) where the photons are concentrated near a circumference of the circle formed by the defect air cylinders.

### Fifth Design

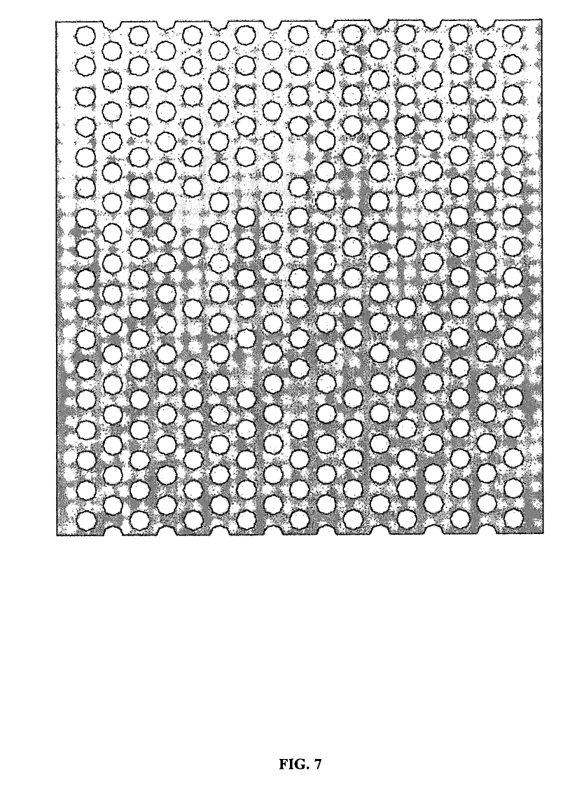

FIG. 7 shows a fourth design where twelve air cylinders of a 2D photonic crystal having a triangular lattice of air cylinders are removed to form twelve different resonant cavities. The twelve resonant cavities can be arranged in a supersymmetric hexagonal array. In certain embodiments, emitters can be included in each of the resonant cavity of the supersymmetric cavity array. The emission of the emitter-field array can interact through a coherent field distributed among the various resonant cavities, which can provide increased intensity of the emission. Moreover, coherent dipole interactions can also be generated by such a design. The slow-group velocity modes in the supersymmetric resonant cavity array can also allow stronger field intensity for interacting with the emitters.

### Sixth Design

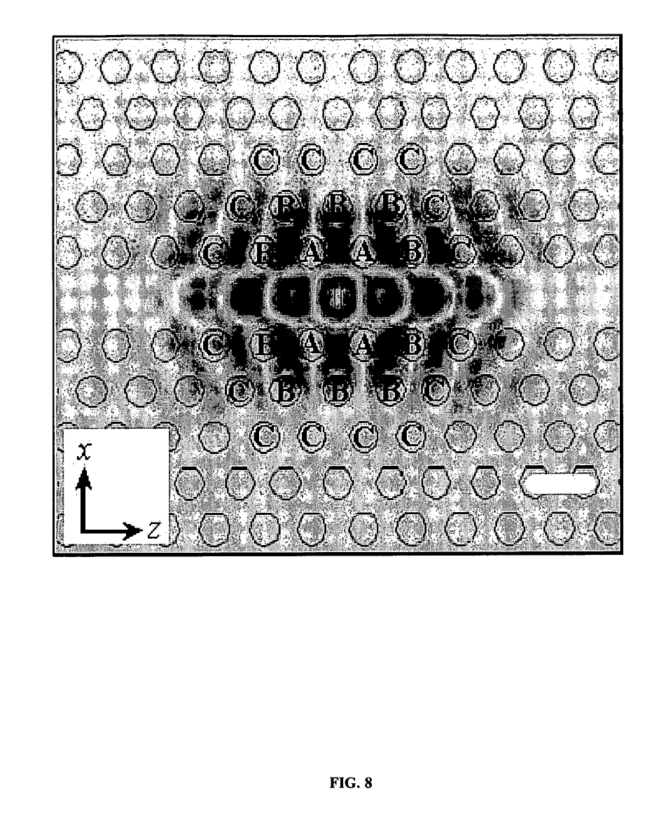

FIG. 8 shows heterostructure mode-gap cavities where four of the air cylinders nearest to the resonant cavity have been displaced slightly from the triangular array (see E. Kuramochi, M. Notomi, S. Mitsugi, A. Shinya, and T. Tanabe, Ultrahigh-Q photonic crystal nanocavities realized by the local width modulation of a line defect, Appl. Phys. Lett. 88, 041112 (2006); and B.-S. Song, S. Noda, T. Asano, and Y. Akahane, Ultra-high-Q photonic double-heterostructure resonant cavity, Nature Materials 4, 207 (2005), the content of which are hereby incorporated by reference herein in their entirety). In FIG. 8, location of air cylinders labeled A, B, and C can be slightly displaced in the x and -x directions to form a slightly larger waveguide structure near the resonant cavity. For example, air cylinders labeled A can be displaced by an amount x, air cylinders labeled B can be displaced by an amount 2x/3, and air cylinders labeled C can be displaced by an amount x/3, where x can be any suitable number. For example, when the lattice constant of the triangular array of air cylinders is 420 nm, the radius of the air cylinders is 108 nm, and the thickness of the slab is 204 nm, and the width of the waveguide is about 641 nm, x can range from about 3 to 30 nm, where x=9 nm can provide the maximum quality factor. The mode-gap resonant cavities have shown Q ranging from about 10,000 to about 800,000 (see T. Uesugi, B.-S. Song, T. Asano, and S. Noda, Investigation of optical nonlinearities in an ultra-high-Q Si resonant cavity in a two-dimensional photonic crystal slab, Optics Express 14, 377 (2006); X. Yang, M. Yu, and C. W. Wong, to be published, the content of which are hereby incorporated by reference herein in their entirety).

### Seventh Design

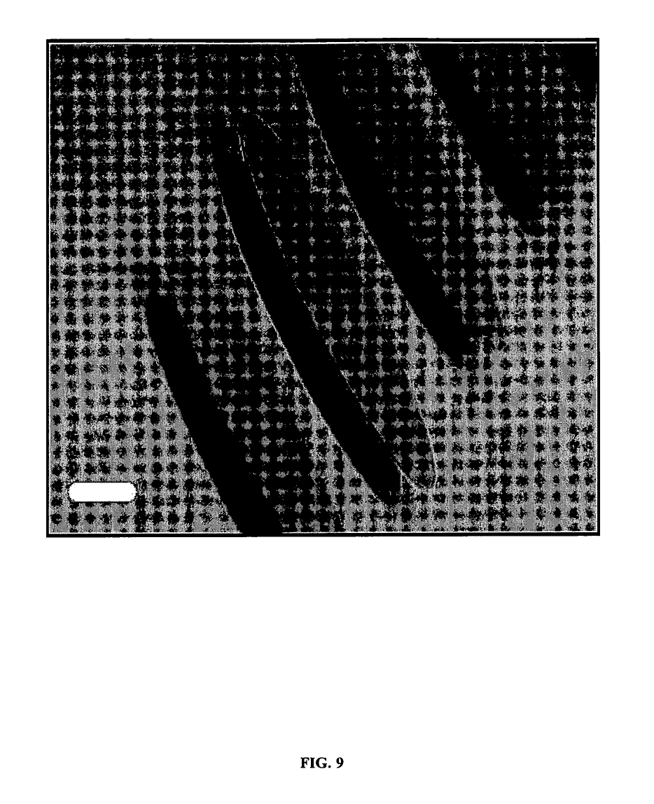

In addition to resonant cavities formed in photonic crystals, FIG. 9 also shows microdisks having high-Q resonances (e.g., from about 10,000 and higher) and directional emission (see J. Wiersig and M. Hentschel, Unidirectional light emission from high-Q modes in optical microcavities, Phys. Rev. A 73, 031802 (R) (2006), the content of which is hereby incorporated by reference herein in its entirety). These microdisks can also develop whispering gallery modes and can have modal volumes that are somewhat larger than photonic crystal resonant cavities.

### OTHER DESIGN EMBODIMENTS

Numerous different embodiments of the invention can be envisioned, as will be readily apparent to one of ordinary skill in the art. Generally, resonant cavity can include standing-wave monopole photonic crystal resonant cavities, standing-wave dipole photonic crystal resonant cavities, traveling-wave whispering gallery mode (WGM) resonant cavities, and the like. For example, photonic crystal resonant cavities can include any suitable 1D, 2D, or 3D photonic crystals with a defect having one or more emitters contained therein, where the emitted photons can be coupled to transverse-electric-like modes of the resonant cavities. Other suitable 2D photonic crystal structures include square lattices, rhombohedral lattices, rectangular lattices, etc. that have suitable band structures. Other suitable 3D photonic crystal structures include inverse-opal structures, diamond lattice of particles, Lincoln log structures, and the like. Other non-photonic crystal based structures having traveling-wave WGM resonant cavities can include microdisks, microtoroids, microrings, photonic crystal WGM resonant cavities, and the like.

### Emitters

Various different emitters can be utilized in the present invention. For example, quantum dot nanocrystals are exemplary emitter materials capable of spontaneous emission. Quantum dots are nano-sized crystals that can confine electrons, holes, or electron-hole pairs (so called “excitons”) to a region that is commensurate with the de Broglie's wavelength of electrons. Such confinement of the excitons lead to discrete quantized energy levels, much like an atom. These energy levels can be controlled by changing the size, shape, and the material they are made of.

For example, lead sulfide (PbS) quantum dots, which emit around 1.55 μm, may be utilized as suitable emitters. Additional optical properties of PbS nanocrystals can be found in I. Kang, and F. W. Wise, J. Opt. Soc. Am. B. vol. 14, (1997), p. 1632; R. S. Kane, R. E. Cohen, and R. Silbey, J. Phys. Chem. vol. 100, (1996), p. 7928; and B. L. Wehrenberg, C. Wang, and P. Guyot-Sionnest, J. Phys. Chem. B. vol. 106, (2002) p. 10634. As described therein, the relaxation lifetimes, T21, for first excited excitons are relatively large (about 400 ns as compared to about 1 ns for visible light emitting CdSe nanocrystals) due to strong screening effects arising from the geometry and high optical dielectric constants. Based on the radiative relaxation time, τ₂₁, of the PbS quantum dots, the exciton decay rate (γ) can be calculated to be approximately 20 MHz. As described above, the resonant resonant cavity can be designed so that it is tuned to the resonance of the lowest energy excitons of the PbS nanocrystal.

Suitable emitters can be fabricated by numerous different methods. For example, quantum dot semiconductor nanocrystals can be colloidally synthesized to form a suitable deposition solution (see R. D. Schaller, M. A. Petruska, and V. I. Klimov, Tunable Near-Infrared Optical Gain and Amplified Spontaneous Emission Using PbSe Nanocrystals, J. Phys. Chem. B 107, 13765 (2003); D. V. Talapin and C. B. Murray, PbSe Nanocrystal Solids for n- and p-Channel Thin Film Field-Effect Transistors, Science 310, 86 (2005); E. H. Sargent, Infrared Quantum Dots, Advanced Materials 17, 515 (2005); and K. R. Choudhury, Y. Sahoo, T. Y. Ohulchanskyy, and P. N. Prasad, Efficient photoconductive devices at infrared wavelengths using quantum dot-polymer nanocomposites, Appl. Phys. Lett. 87, 073110 (2005), the content of which are hereby incorporated by reference herein in their entirety).

### Several Design Notes

For several of the resonant cavity designs described above, cavity decay rates κ=ω/2Q (where Q is the cavity quality factor, and ω is the cavity resonance) of about 330 GHz can be expected. The Rabi frequency can also be calculated according to formula presented in Vu\check{c}ković (see J. Vu\check{c}ković, M. Pelton, A. Scherer, Y. Yamamoto, Phys. Rev. A, 66, 023808 (2002), the content of which is hereby incorporated by reference herein in its entirety) to be approximately 790 GHz.

These numbers suggest that devices of the present invention can meet the criteria for strong coupling given excellent spectral and spatial alignments of cavity field and exciton for a single emitter coupling. For slightly off-resonant exciton-field coupling, the predicted Purcell factors can range between 7 and 30, thereby allowing for a significant increase in spontaneous emission rates. Quality factors of 10³ offer reasonable linewidths for resonant exciton coupling.

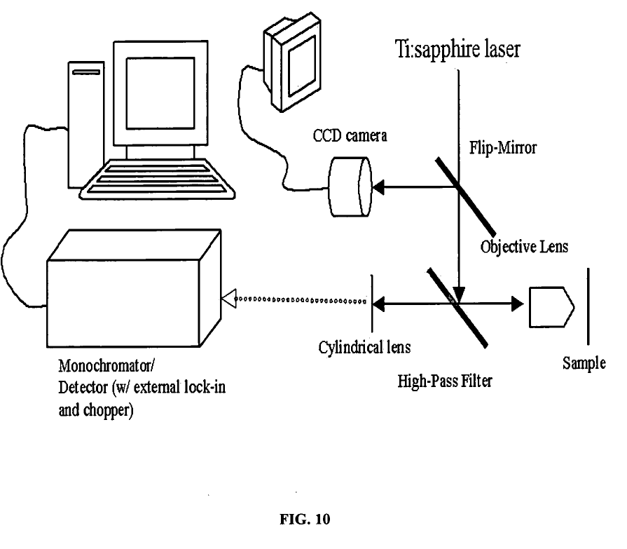

It should also be noted that additional components may be utilized as needed for device operation. For example, the device may be optically pumped to cause the emitters to emit photons. For example, 800 nm Ti:sapphire laser reflecting off a high-pass filter and passing through a microscope objective lens of high numerical aperture can be utilized to excite the emitters. The emitted frequencies can then be collected either in free space or through a waveguide structure designed into the photonic crystal. For example, the emission can be collected using the same microscope objective, passed through the filter, and analyzed using a liquid-nitrogen cooled Ge photodetector mounted on a monochromator (e.g., JYHoriba Triax 320 monochromator). A schematic of such an optical setup is shown in FIG. 10.

Moreover, electroluminescence may also be utilized to excite the emitters in the resonant cavity system. For example, by embedding IV-VI nanocrystals in polymer matrices (see L. Bakueva, S. Musikhin, M. A. Hines, T.-W. F. Chang, M. Tzolov, G. D. Scholes, and E. H. Sargent, Size-tunable infrared (1000-1600 nm) electroluminescence from PbS quantum-dot nanocrystals in a semiconducting polymer, Appl. Phys. Lett. 82, 2895 (2003); and K. R. Choudhury, Y. Sahoo, T. Y. Ohulchanskyy, and P. N. Prasad, Efficient photoconductive devices at infrared wavelengths using quantum dot-polymer nanocomposites, Appl. Phys. Lett. 87, 073110 (2005), the content of which are hereby incorporated by reference herein in their entirety), electroluminescence and photoconductivity measurements were performed in indium-tin-oxide-coated substrates. Reported internal quantum efficiencies were at 1.2% and 3% respectively.

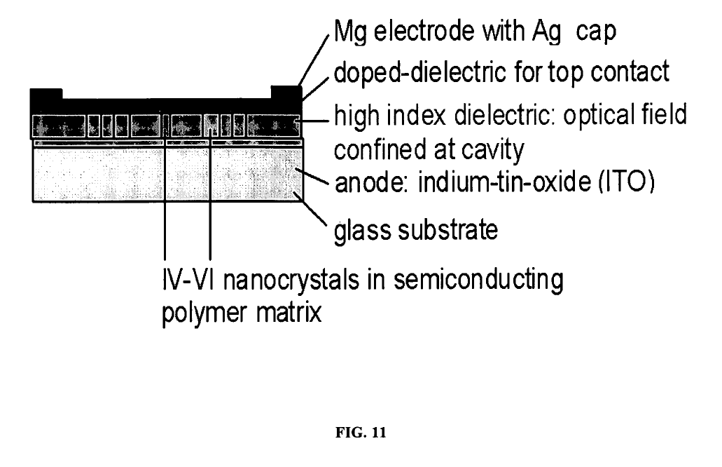

FIG. 11 shows an exemplary cross-section of an electrically pumped nanocrystal-cavity system. As shown, an ITO electrode can be deposited on top of a glass substrate, whereupon the resonant cavity device can be formed. The resonant cavity device can further be capped with a doped-dielectric and a magnesium electrode protected with silver on top.

Any other suitable designs, readily apparent to ordinary skill in the art, are encompassed by the present invention. For example, field-effect electroluminescence, wherein electron and holes are sequentially injected, can also be utilized to electrically luminesce the emitters in the resonant cavity (see R. J. Walters, G. I. Bourianoff and H. A. Atwater, Field-effect electroluminescence in silicon nanocrystals, Nature Materials 4, 143 (2005), the content of which is hereby incorporated by reference herein in its entirety).

The cavity can also be designed to have efficient extraction, either coupled into an integrated waveguide or a critically-coupled tapered fiber (see K. Srinivasan, P. E. Barclay, M. Borselli, O. Painter, Optical-fiber-based measurement of an ultrasmall volume high-Q photonic crystal microcavity, Phys. Rev. B, Rapid Communications 70, 081306(R) (2004), the content of which is hereby incorporated by reference herein in its entirety). Furthermore, a solid-state implementation can provide an invariant location of the quantum emitter with respect to the cavity, as well as significantly smaller cavity modal volumes.

In addition, the cavity interaction can increase the fraction of emitted photons captured into useful directions (of the cavity mode), instead of 4π steridians (see M. Pelton, C. Santori, J. Vuckovic, B. Zhang, G. S. Solomon, J. Plant, and Y. Yamamoto, Efficient Source of Single Photons: A Single Quantum Dot in a Micropost Microcavity, Phys. Rev. Lett. 89, 233602 (2002), the content of which is hereby incorporated by reference herein in its entirety).

### Fabrication

Such resonant cavity designs may be fabricated in any number of different ways. It should be noted that the systems of the present invention may be well-suited for large-array processing and nanofabrication. For example, photolithography or electron beam lithography techniques can be utilized to generate a designed pattern on a photoresist, develop the photoresist, and etch away certain exposed portions of the silicon to obtain the air cylinders.

The infiltration of PbS nanocrystals can be accomplished by any suitable techniques. In certain cases, the nanocrystals can be infiltrated into the air cylinders via capillary forces. For example, the photonic crystal can be immersed in a solution containing the nanocrystals. For example, the solution can contain toluene, PMMA, and nanocrystals. A thin layer of nanocrystal can also be spun onto the photonic crystal surface. Robotic deposition of nanocrystal solutions preferentially into certain holes of the photonic crystal, such as the defect air cylinders, can also be carried out.

Moreover, additional or alternative processing steps may be able to isolate the nanocrystals in the cavity regions. For example, after solution casting from a solution containing nanocrystals, PMMA, and toluene, e-beam lithography may be utilized to depolymerize the PMMA and remove the nanocrystals that are not in the resonant cavity.

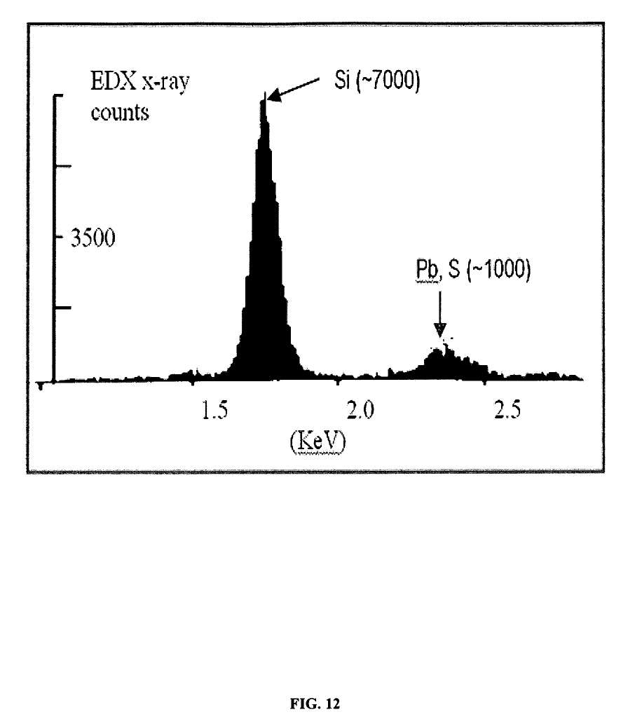

FIG. 12 shows an energy dispersive x-ray (EDX) spectrum of a PbS quantum dot infiltrated into the air cylinders of a 2D silicon photonic crystal. As shown, peaks for Si (˜7000), Pb (˜1000), and S (˜1000) arise with a signal-to-noise ratio of about 5:1 when excited for 100 secs at 10 kV, although the Pb and S peaks are nearly indistinguishable due to the proximity of their respective x-ray emission lines. Any alternative and/or additional methods, such as atomic force microscopy, scanning electron microscopy, infrared spectroscopy, and the like, can be utilized to verify infiltration of the nanocrystals into the 2D photonic crystal structure.

### Applications

Resonant cavity-emitter devices of the present invention can be utilized in numerous different types of applications. For example, nanocrystal-resonant cavity system of the present invention can emit indistinguishable, single photons on demand when excited in any of the methods described above. Such single photon sources can be useful in optical quantum computing, memory devices, quantum repeaters, bosonic exciton lasers, thresholdless laser, and the like.

### Single Photon Sources

Single photon sources can have applications in quantum information networks (flying qubits) and quantum computing (standing qubits) (see J. I. Cirac, P. Zoller, H. J. Kimble, and H. Mabuchi, Quantum State Transfer and Entanglement Distribution among Distant Nodes in a Quantum Network, Phys. Rev. Lett. 78, 3221 (1997); E. Peter, P. Senellart, D. Martrou, A. Lemaitre, J. Hours, J. M. Gérard, and J. Bloch, Exciton-Photon Strong-Coupling Regime for a Single Quantum Dot Embedded in a Microcavity, Phys. Rev. Lett. 95, 067401 (2005); S. Nuβmann, M. Hijlkema, B. Weber, F. Rohde, G. Rempe, and A. Kuhn, Submicron Positioning of Single Atoms in a Microcavity, Phys. Rev. Lett. 95, 173602 (2005); L.-M. Duan and H. J. Kimble, Scalable Photonic Quantum Computation through Cavity-Assisted Interactions, Phys. Rev. Lett. 92, 127902 (2004); Q. A. Turchette, C. J. Hood, W. Lange, H. Mabuchi, and H. J. Kimble, Measurement of Conditional Phase Shifts for Quantum Logic, Phys. Rev. Lett. 75, 4710 (1995); M. S. Zubairy, M. Kim, M. O. Scully, Cavity-QED-based quantum phase gate, Phys. Rev. A 68, 033820 (2003); A. Jose and M. Xiao, Phase gate with a four-level inverted-Y system, Phys. Rev A 72, 062319 (2005); T. Pellizzari, S. A. Gardiner, J. I. Cirac, and P. Zoller, Decoherence, Continuous Observation, and Quantum Computing: A Cavity QED Model, Phys. Rev. Lett. 75, 3788 (1995); and S. J. van Enk, J. I. Cirac, and P. Zoller, Photonic Channels for Quantum Communication, Science 279, 205 (1998), the content of which are hereby incorporated by reference herein in their entirety).

In the strong coupling regime, the strongly-coupled open emitter-resonant cavity quantum system can be significantly perturbed by the detection event (see P. R. Berman, Cavity Quantum Electrodynamics, Academic Press, New York (1994), the content of which is hereby incorporated by reference herein in its entirety), collapsing the wavefunction and leading to g⁽²⁾(0)→0. This can be understood as a stochastic renormalization of the cavity emission rate after the first photon emission. (In the weak coupling regime, the perturbation generally appears to have a small effect on the photon emission.) In strongly coupled emitter-resonant cavity systems, the probability for generation of single photons can approach unity (possibly limited by cavity losses) within a time period T (see J. McKeever, A. Boca, A. D. Boozer, R. Miller, J. R. buck, A. Kuzmich, and H. J. Kimble, Deterministic Generation of Single Photons from One Atom Trapped in a Cavity, Science 303, 1992 (2004); and H. J. Kimble, M. Dagenais, and L. Mandel, Photon antibunching in resonance fluorescence, Phys. Rev. Lett. 39, 691 (1977), the content of which is hereby incorporated by reference herein in its entirety). Hence, the strongly coupled emitter-resonant cavity systems can be termed “deterministic” single photon sources. Time period T can be a few times of (1/g) (see D. L. Zhou, B. Sun, C. P. Sun, and L. You, Generating entangled photon pairs from a cavity-QED system, Phys. Rev. A 72, 040302 (2005), the content of which is hereby incorporated by reference herein in its entirety). Moreover, multiple regions for near-zero multi-photon probability, each illustrating nonclassical characteristics, can exist (see P. R. Berman, Cavity Quantum Electrodynamics, Academic Press, New York (1994), the content of which is hereby incorporated by reference herein in its entirety). It should also be noted that even when there is more than one emitter, the dynamic processes can be significantly perturbed by the detection event in the strong coupling regime.

One performance metric of a single photon source can be the second-order intensity autocorrelation function g⁽²⁾(τ), where

$$\frac{1}{2} < {n}^{⋒} {>}^{2} {g}^{( 2 )} ( 0 )$$

denotes the probability of two or more photons per pulse with g⁽²⁾(0) being the autocorrelation at zero time delay rbetween the first and second photons and <\hat{n}> being the mean photon number per pulse (and can be on the order of about 0.1 in current realistic single photon sources). The quantum optical phenomenon of correlated and reduced probability of emission of a second photon immediately after the first photon is termed antibunching. In ideal sub-Poissonian sources, g⁽²⁾(0) is zero where one photon is emitted at a time; in realistic implementations, g⁽²⁾(0) can approach 0.1 or less in antibunched single photon sources (in comparison with classical Poissonian sources with g⁽²⁾(0)≧1).

Furthermore, reversible Rabi energy exchange between mixed exciton-field states can enable new capabilities, such as allowing the emitter-resonant cavity system to serve as a node for a quantum network (see J. McKeever, A. Boca, A. D. Boozer, R. Miller, J. R. buck, A. Kuzmich, and H. J. Kimble, Deterministic Generation of Single Photons from One Atom Trapped in a Cavity, Science 303, 1992 (2004); H. J. Kimble, M. Dagenais, and L. Mandel, Photon antibunching in resonance fluorescence, Phys. Rev. Lett. 39, 691 (1977); and D. Bouwmeester, A. Ekert A. Zeilinger, ed., The Physics of Quantum Information, Springer, New York, 2000: (A) H.-J. Briegel, S. J. van Enk, J. I. Cirac, and P. Zoller, Quantun Networks I: Entangling Particles at Separate Locations, pp 192-197; (B) H. C. Nagerl, D. Beibfried, F. Schmidt-Kaler, J. Eschner, R. Blatt, M. Brune, J. M. Raimond, S. Haroche, Cavity QED-Experiments: Atoms in Cavities and Trapped Ions, pp 134-162, the content of which are hereby incorporated by reference herein in their entirety). Qubits in the form of single photons may be favored in certain embodiments because they allow ease of fast and long-distance communications through fiber networks while strongly coupled nanocrystal-resonant cavities serve as nodes in the quantum-computing network.

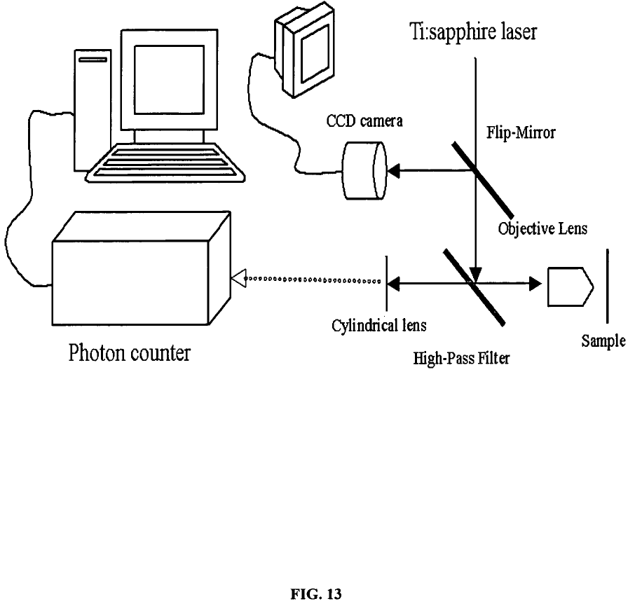

FIG. 13 shows an exemplary setup of a single photon source wherein a photon counting source may be utilized in lieu of the monochromator/detector of FIG. 10. Here, the energy of the Ti:sapphire laser can be adjusted so that the energy received by the resonant cavity structure of the present invention does not emit more than a single photon (as measured by the photon counting source).

### Indistinguishable Photon Sources

For quantum computing, quantum indistinguishability (identical wavefunction of the emitted photon; overlap→1), in addition to near-unity single photon probability and high efficiency, it may be beneficial to achieve two-photon interference, even when resonantly excited. To maximize the indistinguishability, the radiative lifetime can be designed to be shorter than the dephasing lifetime but longer than the higher-order excited state to first excited state relaxation lifetimes (see C. Santori, D. Fattal, J. Vuckovic, G. S. Solomon, Y. Yamamoto, Indistinguishable photons from a single-photon device, Nature 419, 594 (2002), the content of which is hereby incorporated by reference herein in its entirety). Dephasing can also to lead to spectral broadening, reduced quantum efficiencies, and reduction of oscillation amplitude in the strong-coupling regime (see G. Cui and M. G. Raymer, Emission spectra and quantum efficiency of single-photon sources in the cavity-QED strong-coupling regime, Phys. Rev. A 73, 053807 (2006), the content of which is hereby incorporated by reference herein in its entirety). Hence, to achieve optimal quantum indistinguishability, control of the radiative lifetime of the emitters and resonant cavity enhancements may be needed to achieve radiative lifetimes shorter than the dephasing lifetime of the emitters.

It should be noted that the unmodified radiative lifetime (1/γ) of lead chalcogenide nanocrystals can be relatively long at ˜100 ns (see B. L. Wehrenberg, C. Wang, and P. Guyot-Sionnest, Interband and Intraband Optical Studies of PbSe Colloidal Quantum Dots, J. Phys. Chem. B 106, 10634 (2002), the content of which is hereby incorporated by reference herein in its entirety), compared to other nanocrystals or quantum dots (approximately hundreds of ps), due to strong screening effects (from high optical dielectric constants and geometry) (see I. Kang and F. W. Wise, Electronic structure and optical properties of PbS and PbSe quantum dots, J. Opt. Soc. Am. B 14, 1632 (1997); and R. S. Kane, R. E. Cohen, R. Silbey, Theoretical Study of the Electronic Structure of PbS Nanoclusters, J. Phys. Chem. 100, 7928 (1996), the content of which are hereby incorporated by reference herein in their entirety).

In certain embodiments, the optimal value of modified radiative lifetime for quantum indistinguishability can be approximated to be the square root average of the product of the dephasing lifetime and relaxation lifetime (see C. Santori, D. Fattal, J. Vuckovic, G. S. Solomon, Y. Yamamoto, Indistinguishable photons from a single-photon device, Nature 419, 594 (2002), the content of which is hereby incorporated by reference herein in its entirety). The dephasing lifetime (or equivalently coherence length divided by c) can be due to loss of phase coherence (elastic) or population relaxation (inelastic). Taking the exemplary quantum dots as emitters, some approximate values for relaxation lifetimes and dephasing lifetimes can be mentioned. The lead salt nanocrystal relaxation lifetimes is measured to be approximately about 500 ns, for lower excited states and increasing monotonically with crystallite size for low carrier densities (see J. M. Harbold, H. Du, T. D. Kraus, K-S. Cho C. B. Murray, F. W. Wise, Time-resolved intraband relaxation of strongly confined electrons and holes in colloidal PbSe nanocrystals, Phys. Rev. B 72, 195312 (2005), the content of which is hereby incorporated by reference herein in its entirety). The relaxation lifetime may be dominated by surface ligands and atoms. While dephasing lifetimes has not been reported in lead chalcogenide nanocrystals, in self-assembled InAs quantum dots it is on the order tens of ps to even 2 ns (radiatively limited), increasing with stronger quantum confinement (see W. Langbein, P. Borri, U. Woggon, V. Stavarache, D. Reuter, and A. D. Wieck, Radiatively limited dephasing in InAs quantum dots, Phys. Rev. B 70, 033301 (2004), the content of which is hereby incorporated by reference herein in its entirety).

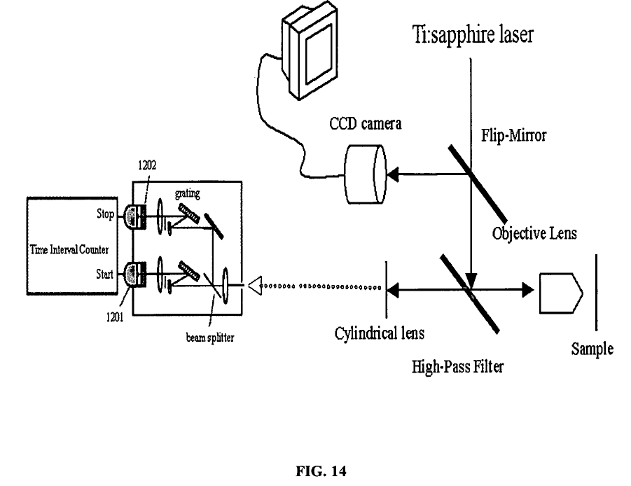

FIG. 14 shows an exemplary setup of an indistinguishable photon source wherein Hanbury-Brown-Twiss interferometer may be utilized in lieu of the monochromator/detector of FIG. 10. Here, the energy of the Ti:sapphire laser can be adjusted until photon counter 1201 and 1202 do not simultaneously detect photons.

### Quantum Key Distribution

Single photons sources can also provide a means for quantum key distribution (QKD), where the quantum mechanical nature of single quanta makes it fundamentally impossible for eavesdropping between a sender (Alice) and the recipient (Bob). A well-developed protocol for quantum key distribution is the Vernam-cipher BB84 protocol (see C. H. Bennett, F. Bessette, G. Brassard, L. Salvail, and J. Smolin, Experimental quantum cryptography, J. Cryptol. 5, 3 (1992); and C. H. Bennett and G. Brassard, in Proc. of the IEEE Int. Conf. on Computers, Systems, and Signal Processing, New York 1984, the content of which is hereby incorporated by reference herein in its entirety), where key bits are encoded in four non-orthogonal polarization states of single photons. Error correction and privacy amplification schemes can be used in this protocol. The rate and distance of the QKD secure communication can be determined by the probability of multi-photon pulses (more than one quantum wavepacket per pulse) in the light sources and the dark count rate in the photodetectors.

Unlike current QKD that use drastic attenuation of classical Poissonian light sources (where the emission of a second photon is independent of the emission of the first photon—that is, there is a non-zero probability of multi-photon pulses), such as pulsed lasers or light-emitting diodes, to approximate single photon sources, the present invention can provide a sub-Poissonian single photon source, because the multi-photon probability can be reduced.

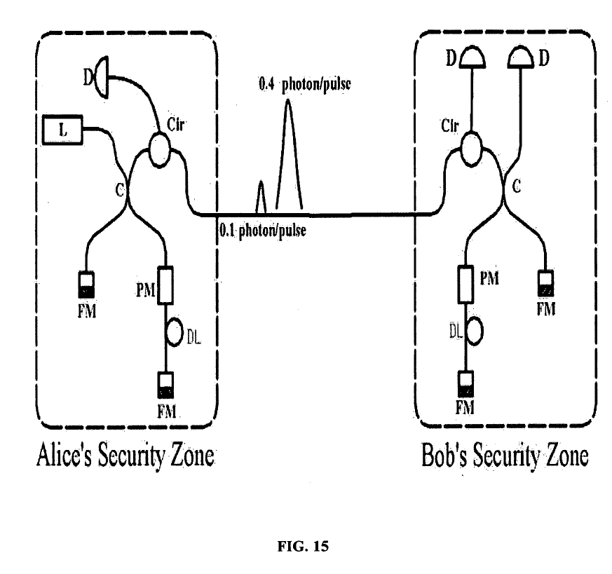

FIG. 15 show an exemplary setup of a QKD system where Alice sends information to Bob using the resonant cavity structure of the present invention. For example, Alice's security zone may contain the resonant cavity structure L designed to operate as a single photon source. The photons can be coupled to a second fiber using fiber coupler C, where one fiber sends the photons directly to a Faraday mirror FM while the other fiber introduces a modulation in phase and a delay through phase modulator PM and delay line DL. Any potential “Trojan horse” photons can be detected by single photon detector D. For example, as shown in FIG. 15, 4 photons per 10 pulse may travel through the first path while 1 photons per 10 pulse may travel through the delay path and be sent to Bob. Bob then may received the encrypted information using a setup similar to that in Alice's security zone, except the resonant cavity structure L is replaced with a single photon detector D to detect the encrypted data. If no “Trojan horse” photons are detected and only the encrypted information is detected, prevention of eavesdropping between Alice and Bob can be assured.

### Quantum Repeaters

The nanocrystal-resonant cavity systems of the present invention (e.g., see FIGS. 6 and 7) can also permit the development of quantum repeaters. While it may be difficult to clone a single quantum since the correlations would be fundamentally broken (see W. K. Wootters and W. H. Zurek, A single quantum cannot be cloned, Nature 299, 802 (1982), the content of which is hereby incorporated by reference herein in its entirety), quantum repeaters (see H.-J. Briegel, W. Dür, J. I. Cirac, and P. Zoller, Quantum Repeaters: The Role of Imperfect Local Operations in Quantum Communication, Phys. Rev. Lett. 81, 5932 (1998); and E. Waks and J. Vuckovic, Dipole Induced Transparency in Drop-Filter Cavity-Waveguide Systems, Phys. Rev. Lett. 96, 153601 (2006), the content of which is hereby incorporated by reference herein in its entirety) that serve to absorb a qubit and then retransmit can be developed. In communications, large arrays of quantum repeaters are desirable, both in each repeater node and in the number of nodes per communication channel.

### Lasers

In addition, systems of the present invention can also permit opportunities for bosonic exciton lasers, one of stimulated emission of exciton polaritons in microcavities (see Y. Yamamoto, F. Tassone, and H. Cao, Semiconductor Cavity Quantum Electrodynamics, Springer, New York (2000); and Y. Yamamto and A. Imamoglu, Mesoscopic Quantum optics, Wiley, New York (1999), the content of which are hereby by incorporated by reference herein in their entirety). In the weak coupling regime, although dephasing may prevent coherent evolution of the nanocrystal-resonant cavity system, the cavity Q could be high enough for the emitted photon to stimulate the emission of a second photon during repumping-permitting lasing. This has been considered even in the case of the cavity linewidth being much smaller than the emitter linewidth, and in the cases of with and without Purcell enhancement. Our colloidal nanocrystal-cavity system provides the possibilities towards silicon-based near-infrared lasers, in both optically- and electrically-pumped regimes. A setup similar to that shown in FIG. 9 may be utilized, where the power of the Ti:sapphire laser can be adjusted to overcome the threshold value to lasing to occur in the resonant cavity structure.

### EXAMPLE

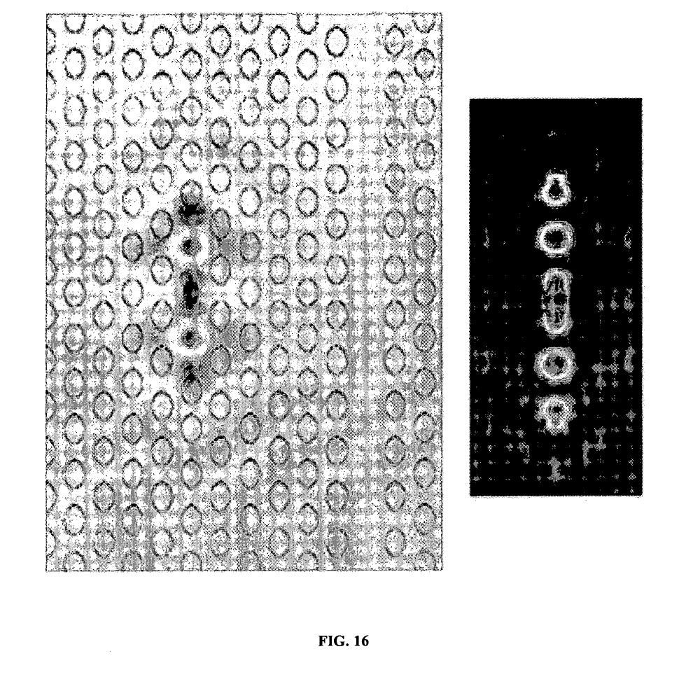

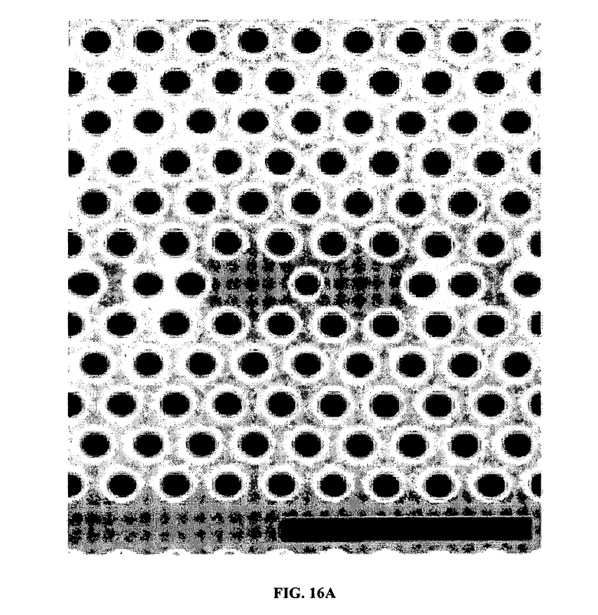

L3 nanocavities in silicon, where three air cylinders are replaced with a center cylinder (see FIG. 16), are used for studying both mid-cavity-plane and evanescent coupling of PbS quantum dots (QD). The design parameters are as follows: a=420 nm, r=0.29a (±10%), r_{c}=0.28a (±10%), and t=0.6a, where a, r, r_{c}, and t represent the lattice parameter, radius of holes, radius of the center hole, and slab thickness, respectively (r_{c}=0.26a (±10%) was also used). All cavities are s1 or s3 detuned (see Akahane et al. Opt. Express, 13, p. 1202 (2005), which is incorporated by reference herein in its entirety). S1 detuning refers to lateral displacement of the air cylinders (2 total) that are near the resonant cavity and s3 detuning refers to later displacement of the 3 air cylinders (6 total) near the resonant cavity.

The silicon photonic crystal devices are fabricated on a SiO₂ cladding and incorporate one or more waveguides (see FIG. 16) that allow for lensed optical fiber-waveguide coupling and characterization of the nanocavities using radiation collection measurements. FIG. 16A shows an SEM image of the fabricated device. The SEM image in FIG. 16A shows a device with s3 detuning where the air cylinders have been laterally (horizontally) displaced 0.176a, 0.025a, and 0.176a on either side of the resonant cavity. The center hole (resonant cavity) has a radius of about 0.308a.

The devices are characterized theoretically using three-dimensional finite-difference time-domain (FDTD) simulations, using a software package with subpixel smoothing for increased accuracy. The simulations indicate a mode volume of about 0.07 μm³. An overall collection efficiency of about 11% is computed for the cavity field mode using the numerical aperture (0.85) of the objective lens used in experiments and the simulated field profile. A collection efficiency of about 8% is estimated for PbS quantum dots in a polymethyl methacrylate (PMMA) thin film.

The designed cavity corresponds to a theoretical Purcell factor of about 100. Spontaneous emission enhancements (E) for single exciton states are estimated using the spatial distribution of the 3D electric field profile and are modified from Fₚ due to spatial and spectral mismatches. Enhancements are computed through a statistical distribution of quantum dots, assuming random exciton polarization, to represent the actual measurements as well as to determine the viability of these devices in low-QD number or single photon operational regimes. Using the collection efficiencies described above and an estimated QD density of 10³/μm², an average overall enhancement of 1.1351 (standard deviation σ:0.1105) is calculated for weakly coupled dots for an assumed F_{PhC} of 0.6 (γₑ=2 MHz, γ_{c}=800 GHz). However, this prediction does not take into account significant sources of enhancements such as exciton-linewidth evolution and QD surface proximity effects and may be altered for the case of high pump-power cavity mapping using ensemble QD.

In the experiments, ensemble PbS nanocrystals are used as a broad-band light source to decorate the resonant modes of the two-dimensional silicon photonic crystal resonator. The nanocrystals are obtained in a mixture of PMMA (5%-15% by weight) and toluene (85%-95% by weight) through Evidot Technologies. The nanocrystals exhibit high photoluminescence (PL) efficiency, room temperature stability, and PL peak around 1500 nm, with a full width at half maximum of about 150 nm. After diluting the commercially obtained sample 2:3 parts by volume in toluene, an overall thin film of approximately 100 nm is achieved at a spin rate of about 5000 rpm. The 100 nm thin film of PMMA (n=1.56) may change the band structure of the photonic crystal as well as shift the cavity resonance and the spatial electric field profile of the cavity mode due to a changed contrast. Nevertheless, these changes can be monitored experimentally due to the presence of waveguides on the devices, enabling cold-cavity characterization.

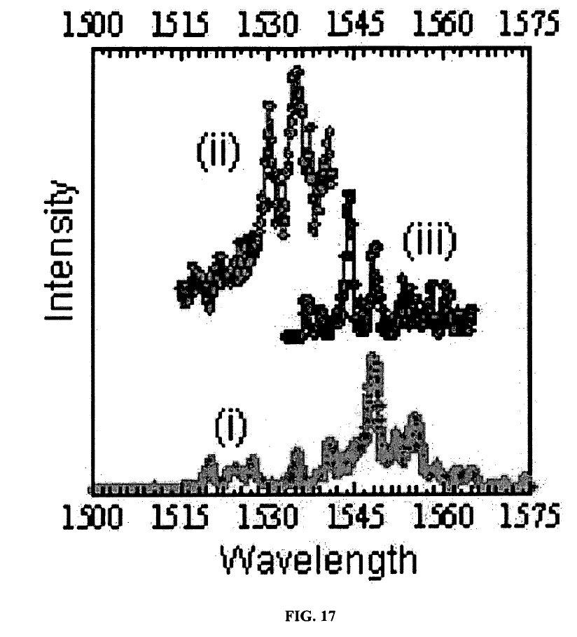

FIG. 17 shows the spectra collected from the radiation of cavity field modes with a 100 nm thin film of PMMA for (i) s3 detuned device where r_{c}=0.308a and λ₀=1548 nm; (ii) s1 detuned device where r_{c}=0.308a after selective PMMA removal and λ₁=1530 nm and λ₂=1534 nm; and (iii) s1 detuned device (0.176a) where r_{c}=0.286a, λ₃=1543 nm, λ₄=1548 nm, and r=0.319a.

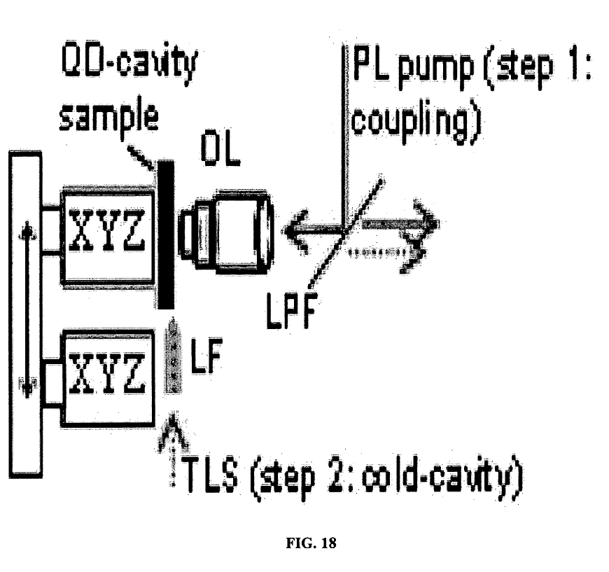

As schematically illustrated in FIG. 18, the experiments are performed in two steps. In step 1, coupling measurements are performed. PbS nanocrystals located near the cavity are excited off resonance using a pulsed Ti:sapphire laser operating at 800 nm with a repetition rate of 80 MHz and pulse duration of 150 fs. The pump signal reaching the nanocrystals is attenuated and the pump fluence after focusing is approximately 10 μJ/cm². The PbS QDs are found to be stable under continuous, intense illumination over a period of hours, and the experiments are repeatable over a period of several days, showing that degradation does not occur due to the laser. The laser light is reflected by a high-pass filter and a 60× objective lens is used to focus the beam. The radiation from the cavity is collected with the same objective lens from a spot of about 2 μm in diameter, dispersed by a 32 cm JY Horiba Triax 320 monochromator, and detected using a liquid-nitrogen cooled Ge detector. An additional high-pass filter is used near the monochromator slit to filter out any signal from the Ti:sapphire laser.

In step 2, waveguide characterization of the cold-cavity modes is performed in the same setup by using a tapered lens fiber butt coupled to an on-chip waveguide. The chip is mounted vertically on a wide-range translation stage that allows for monitoring at the cavity, as well as the chip edge for waveguide to tapered-fiber alignment, by the same objective lens (see FIG. 18). In this case, an Ando tunable laser source operating between 1480 and 1580 nm at 8 dBm peak power is used, and the cavity radiation is collected from the top using the objective lens. Cavity Q of between 500 and 1500 is estimated by fitting Lorentzians to the experimental cold-cavity radiation spectrum for different cavity designs, after the QD have been spin coated (see FIG. 17). In this step, the QDs are not excited by the low power source, and no broadband PL is observed.

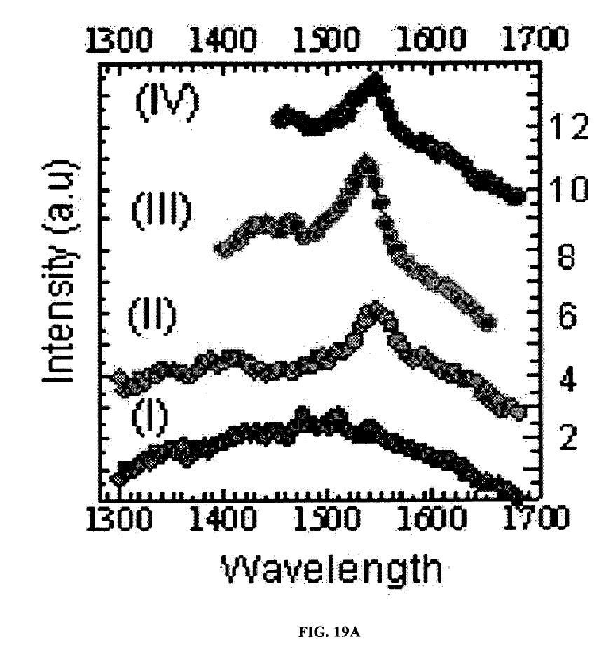

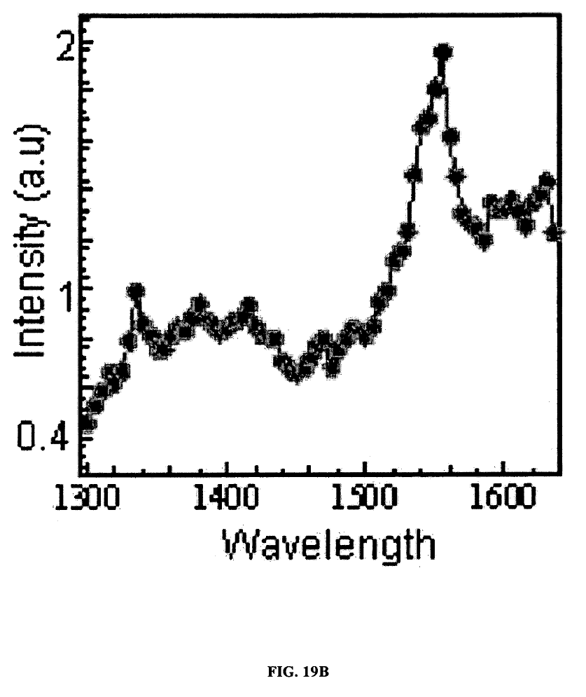

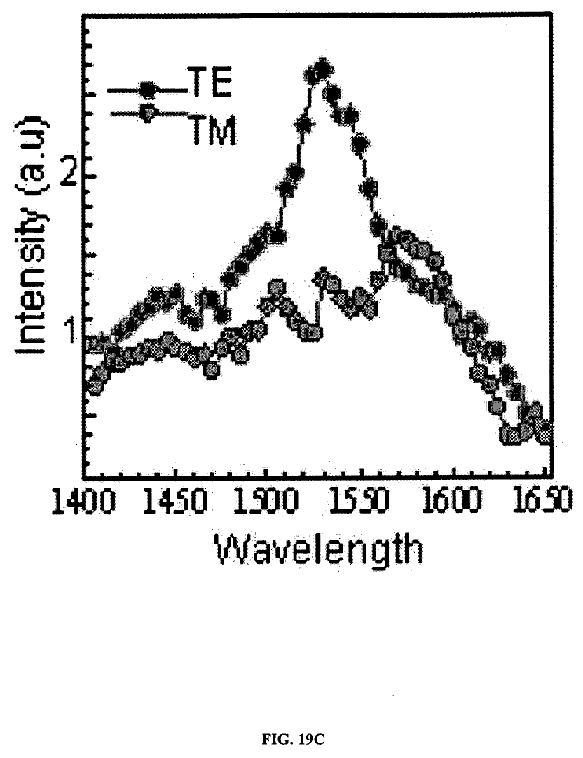

The collection path in step 1 is set up by aligning to the cavity radiation using an IR camera and a broadband laser source for fiber to waveguide excitation, as in the cold-cavity measurements. Once this path is established, the Ti:sapphire laser is pumped to pump the nanocrystals for the coupling experiments. FIG. 19A shows the results of the coupling measurements. Enhancement over the background PL is observed at the cavity, compared to PL collected approximately 10 μm away from the cavity, where the spectrum follows the familiar Gaussian line shape with a full width at half maximum of around 100 nm. As shown, curve I corresponds to the background PL. Curves II through IV correspond to coupling measurement that correspond to cold-cavity characterization of (i) through (iii) in FIG. 17, respectively. The coupled resonances are measured at λ₀=1550 nm, λ₁=1535 nm, and λ₃=1545 nm for curves II through IV, respectively.

The spectrum in FIG. 19B shows the cavity field mode normalized to the background PL for curve II of FIG. 19A. The measurements in step 1 are confirmed with fiber-based characterization of the devices in step 2 above. However, in the coupling measurements, the individual peaks in the cold-cavity radiation spectrum (FIG. 17) are not resolved, and a broader enhanced peak is observed, centered at a cavity mode. For different samples, and depending on whether the PMMA is selectively removed, the coupled resonances are seen to shift and are verified with the corresponding cold-cavity measurements. The observed linewidth is attributed to the large expected homogeneous linewidths of coupled PbS nanocrystals at room temperature. In these experiments, the experimental resolution is at about 5 nm.

As an added verification that the peak is due to coupling of the QDs to the cavity, a linear polarizer is introduced in the collection path. As shown in FIG. 19C, the collected modes show strong polarization dependence where polarization coupling measurements are obtained for s1, r_{c}=0.308a, and λ₅=1535 nm. A polarization ratio of 1.7 is inferred from the polarization extinction measurements. The observed enhanced emission for QD at the cavity resonance is caused due to spontaneous emission enhancement as well as the higher collection efficiency of the cavity field mode compared to uncoupled QD, and matches well with theory.

As shown, coupling of colloidal PbS nanocrystals to silicon photonic crystals at the near infrared and at room temperature is demonstrated. Spontaneous emission enhancements of 100 can be achieved in certain embodiments. The operation of the coupled nanocavity-nanocrystal system in silicon at around 1550 nm is especially promising because of the possibility of a single photon source that can be integrated into the conventional fiber infrastructure and the scalability with silicon complementary metal oxide semiconductor foundries.

As will be readily apparent to one of ordinary skill in the art, there are several attendant advantages of the present invention over that of the prior art. The present invention can permit single photon, indistinguishable, and/or sub-Poissonian light sources at room temperature. Moreover, the emitter-resonant cavity system of the present invention can operate at the near-infrared communications window, permitting long-distance optical fiber transmission of single photons. Furthermore, the present invention may be compatible with large-scale silicon CMOS foundries (through back-end processing of the selectively infiltrated nanocrystals). We also note here that high-Q cavities may be more realizable due to the significantly advanced silicon processing technologies.

Upon review of the description and embodiments of the present invention, those skilled in the art will understand that modifications and equivalent substitutions may be performed in carrying out the invention without departing from the essence of the invention. Thus, the invention is not meant to be limiting by the embodiments described explicitly above, and is limited only by the claims which follow.

What is claimed is:

1. A device comprising:
a structure which comprises at least one resonant cavity having at least one resonant frequency; and
at least one emitter having one or more emission wavelengths that is substantially in the telecommunication wavelengths; wherein
the one or more emission wavelengths are capable of being coupled to the resonant frequency of the resonant cavity so that the one or more emission wavelengths corresponding to the at least one resonant frequency of the at least one resonant cavity are enhanced; and wherein
the device is capable of operating at room temperatures.

2. The device of claim 1, wherein the at least one emitter comprises at least one photoluminescent emitter.

3. The device of claim 2, wherein the at least one emitter comprises quantum dots.

4. The device of claim 3, wherein the at least one emitter comprises lead chalcogenide quantum dots.

5. The device of claim 1, wherein the structure comprises a waveguide coupled to the resonant cavity.

6. The device of claim 1, wherein the structure is a two-dimensional photonic crystal having a triangular lattice of holes.

7. The device of claim 6, wherein the at least one resonant cavity comprises three linearly adjacent holes of the triangular lattice replaced with a smaller diameter hole.

8. The device of claim 6, wherein the at least one resonant cavity comprises three linearly adjacent holes of the triangular lattice replaced with air line defect.

9. The device of claim 6, wherein the at least one resonant cavity comprises one hole of the triangular lattice replaced with a smaller diameter hole.

10. The device of claim 6, wherein the at least one resonant cavity comprises 19 air cylinders of the triangular lattice replaced with 12 smaller air cylinders arranged in a circular pattern to form a whispering gallery mode.

11. The device of claim 6, wherein the at least one resonant cavity comprises twelve different resonant cavities arranged in at the vertices and edges of a hexagon form a supersymmetric resonant cavity array.

12. The device of claim 1, wherein the structure comprises microdisks having whispering gallery modes.

13. The device of claim 1, wherein the quality factor (Q) of the resonant cavity is from about 500 to about 800,000.

14. The device of claim 1, wherein the coupling of the emitted frequencies includes repeated emission and absorption of photons within the resonant cavity.

15. The device of claim 1, wherein the coupling of the emitted frequencies includes modification of the emitted wavelengths through the Purcell effect.

16. The device of claim 1, wherein the at least one emitter comprises at least one electroluminescent emitter.

17. The device of claim 1, wherein the radiative lifetime of the emitter is shorter than the dephasing lifetime of the emitter.

18. A single photon source comprising the device of claim 1.

19. An indistinguishable photon source comprising the device of claim 1.

20. A laser comprising the device of claim 1.

21. A quantum key distribution system comprising the device of claim 1.

22. A quantum computer comprising the device of claim 1.

23. A method for forming a device, the method comprising:
forming a resonant cavity structure,
providing one or more emitters to be coupled with the resonant frequency of the resonant cavity structure; wherein
the one or more emitter have an emission frequency that is substantially in the telecommunication wavelengths; and
the device if capable of operating at room temperatures.
